(19) United States
(12) Patent Application Publication
(10) Pub. No.: US 2014/0212809 A1
(43) Pub. Date: Jul. 31, 2014

(54) PHOTOSENSITIVE RESIN COMPOSITION AND METHOD OF FORMING PATTERN USING THE SAME

(71) Applicant: Samsung Display Co., Ltd., Yongin-City (KR)

(72) Inventors: Jeong Min PARK, Seoul (KR); Ji-Hyun KIM, Seoul (KR); Jung-Soo LEE, Seoul (KR); Hyoc-Min YOUN, Hwaseong-si, Gyeonggi-do (KR)

(73) Assignee: Samsung Display Co., Ltd., Yongin-City (KR)

(21) Appl. No.: 14/140,350

(22) Filed: Dec. 24, 2013

(30) Foreign Application Priority Data
Jan. 31, 2013 (KR) 10-2013-0011189

(51) Int. Cl. G03F 7/038; G03F 7/30

(52) U.S. Cl. CPC G03F 7/038; G03F 7/30
USPC 430/280.1; 430/325

(57) ABSTRACT

A photosensitive resin composition includes an acryl-based copolymer formed by copolymerizing unsaturated carboxylic acid, unsaturated carboxylic acid anhydride, or a mixture thereof and an olefin-based unsaturated compound or a mixture of olefin-based unsaturated compounds, a photoinitiator represented by the following Chemical Formula 1 or 2, a multifunctional acrylate oligomer, a multifunctional monomer having an ethylenically unsaturated bond, and a melamine crosslinking agent.

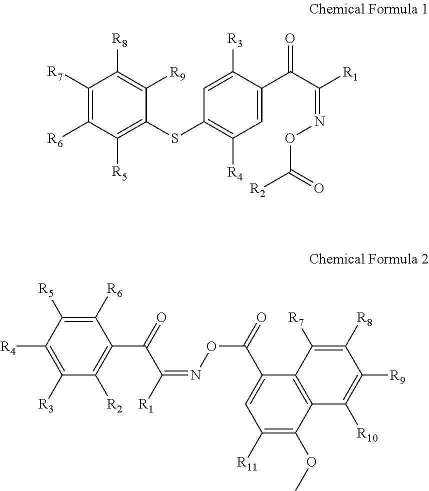

### CROSS-REFERENCE TO RELATED APPLICATION

This application claims priority to and the benefit of Korean Patent Application No. 10-2013-0011189 filed in the Korean Intellectual Property Office on Jan. 31, 2013, the entire contents of which are incorporated herein by reference.

### BACKGROUND

(a) Technical Field

The present invention relates to a photosensitive resin composition and a method of forming a pattern using the same.

(b) Description of the Related Art

In general, flat panel display are an extensively used display device, and there are various kinds of flat panel displays, such as a liquid crystal displays (LCD) and organic light emitting displays (OLED).

In the course of forming the flat panel display, a photo process may be used in order to pattern a layer. In this case, a photoresist material is used. Alternatively, a layer may be directly formed by exposing and developing the photoresist material.

An insulating layer, a column spacer, an overcoat layer, and a color filter layer may be formed by using the photoresist. The photoresist can affect the resolution, adherence, retention rate, and the like of the various layers, depending upon the components that constitute the photosensitive resin composition for forming the photoresist.

The above information disclosed in this Background section is only for enhancement of understanding of the background and therefore it may contain information that does not form the prior art that is already known to a person of ordinary skill in the art.

### SUMMARY

A photosensitive resin composition having excellent resolution and retention rate is provided.

Further, a display device is provided having no greenish defects and excellent adherence when an organic layer of the display device is formed.

In one aspect, a photosensitive resin composition includes an acryl-based copolymer formed by copolymerizing i) at least one of an unsaturated carboxylic acid, an unsaturated carboxylic acid anhydride, and a mixture thereof and ii) at least one of an olefin-based unsaturated compound or a mixture of olefin-based unsaturated compounds, a photoinitiator represented by the following Chemical Formula 1 or 2, a multifunctional acrylate oligomer, a multifunctional monomer having an ethylenically unsaturated bond, and a melamine crosslinking agent.

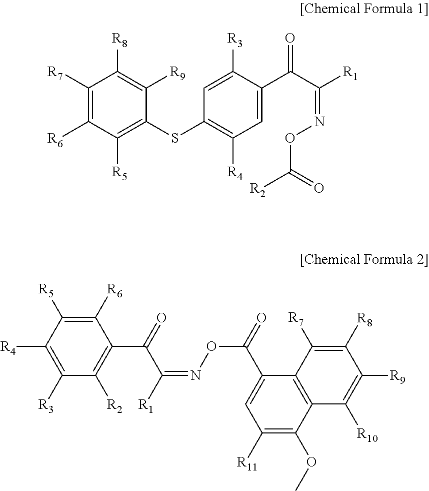

Herein, in Chemical Formula 1, R1 is an alkyl group having 1 to 8 carbon atoms, R2 is a phenyl group or an alkyl group having 1 to 8 carbon atoms, and R3 to R9 are each independently hydrogen, a halogen atom, or an alkyl group having 1 to 8 carbon atoms. In Chemical Formula 2, R1 is an alkyl group having 1 to 8 carbon atoms, and R2 to R11 are each independently hydrogen, a halogen atom, or an alkyl group having 1 to 8 carbon atoms.

The melamine crosslinking agent may be represented by the following Chemical Formula 3.

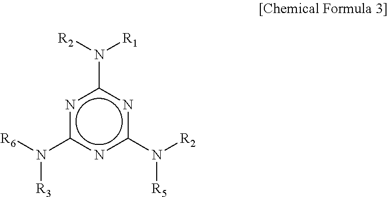

Herein, in Chemical Formula 3, R1, R2, and R3 are each independently —CH₂O (CH₂)ₙCH₃ (n is an integer of 0 to 3), and R4, R5, and R6 are each independently or simultaneously hydrogen, —(CH₂)OH, or —CH₂O (CH₂)ₙCH₃ (n is an integer of 0 to 3).

The photosensitive resin composition may further include a silane coupling agent.

The silane coupling agent may include at least one selected from the group including (3-glycideoxypropyl)trimethoxysilane, (3-glycideoxypropyl)triethoxysilane, (3-glycideoxypropyl)methyldimethoxysilane, (3-glycideoxypropyl)methyldiethoxysilane, (3-glycideoxypropyl)dimethylethoxysilane, 3,4-epoxybutyltrimethoxysilane, 3,4-epoxybutyltriethoxysilane, 2-(3,4-epoxycyclohexyl)ethyltrimethoxysilane, 2-(3,4-epoxycyclohexyl)ethyltriethoxysilane, aminopropyltrimethoxysilane, aminopropyltriethoxysilane, 3-triethoxysili-N-(1,3dimethyl-butylidene)propylamine, N-2(aminoethyl)3-aminopropyltrimethoxysilane, N-2(aminoethyl)3-aminopropyltriethoxysilane, N-2(aminoethyl)3-aminopropylmethyldimethoxysilane, N-phenyl-3-aminopropyltrimethoxysilane, and (3-isocyanatepropyl)triethoxysilane.

A content of the acryl-based copolymer obtained after 5 parts by weight to 40 parts by weight of the acryl-based copolymer of at least one of the unsaturated carboxylic acid, the unsaturated carboxylic acid anhydride, and the mixture thereof and 60 parts by weight to 95 parts by weight of the acryl-based copolymer of at least one of the olefin-based unsaturated compound and the mixture olefin-based unsaturated compounds are copolymerized and an unreacted monomer is removed may be about 100 parts by weight, the content of the photoinitiator may be about 0.1 parts by weight to about 30 parts by weight of the acryl-based copolymer, the content of the multifunctional acrylate oligomer may be about 1 part by weight to about 50 parts by weight of the acryl-based copolymer, the content of the multifunctional monomer having the ethylenically unsaturated bond may be about 1 part by weight to about 50 parts by weight of the acryl-based copolymer, the content of the melamine crosslinking agent may be about 0.1 parts by weight to about 30 parts by weight of the acryl-based copolymer, and the content of the silane coupling agent may be about 0.1 parts by weight to about 30 parts by weight of the acryl-based copolymer.

The unsaturated carboxylic acid, the unsaturated carboxylic acid anhydride, or the mixture thereof may include at least one selected from the group including acrylic acid, methacrylic acid, maleic acid, fumaric acid, citraconic acid, mesaconic acid, itaconic acid, and anhydrides thereof.

The olefin-based unsaturated compound may include at least one selected from the group including methylmethacrylate, ethylmethacrylate, n-butyl methacrylate, sec-butyl methacrylate, tert-butyl methacrylate, methylacrylate, isopropyl acrylate, cyclohexyl methacrylate, 2-methylcyclo hexylmethacrylate, dicyclopentenylacrylate, dicyclopentanylacrylate, dicyclopentenylmethacrylate, dicyclopentanylmethacrylate, 1-adamantyl acrylate, 1-adamantyl methacrylate, dicyclopentanyloxyethylmethacrylate, isoboronylmethacrylate, cyclohexylacrylate, 2-methylcyclohexylacrylate, dicyclopentanyloxyethylacrylate, isoboronylacrylate, phenylmethacrylate, phenylacrylate, benzylacrylate, 2-hydroxyethylmethacrylate, styrene, σ-methyl styrene, m-methyl styrene, p-methyl styrene, vinyltoluene, p-methoxy styrene, 1,3-butadiene, isoprene, 2,3-dimethyl 1,3-butadiene, acrylic acid glycidyl, methacrylic acid glycidyl, α-ethylacrylic acid glycidyl, α-n-propylacrylic acid glycidyl, α-n-butylacrylic acid glycidyl, acrylic acid-β-methylglycidyl, methacrylic acid-β-methylglycidyl, acrylic acid-β-ethylglycidyl, methacrylic acid-β-ethylglycidyl, acrylic acid-3,4-epoxybutyl, methacrylic acid-3,4-epoxybutyl, acrylic acid-6,7-epoxyheptyl, methacrylic acid-6,7-epoxyheptyl, α-ethylacrylic acid-6,7-epoxyheptyl, o-vinylbenzylglycidylether, m-vinylbenzylglycidylether, p-vinylbenzylglycidylether, and methacrylic acid 3,4-epoxycyclohexyl.

A polystyrene-converted weight average molecular weight of the acryl-based copolymer may be about 3000 to about 30000.

The multifunctional acrylate oligomer may have 2 to 20 functional groups and may include at least one selected from the group including an aliphatic urethane acrylate oligomer, an aromatic urethane acrylate oligomer, an epoxy acrylate oligomer, an epoxy methacrylate oligomer, a polyester acrylate oligomer, a silicon acrylate oligomer, a melamine acrylate oligomer, and a dendritic acrylate oligomer.

The multifunctional monomer having the ethylenically unsaturated bond may include at least one selected from the group including 1,4-butanediol diacrylate, 1,3-butyleneglycol diacrylate, ethyleneglycol diacrylate, trimethylolpropane diacrylate, trimethylolpropane triacrylate, pentaerythritol triacrylate, pentaerythritol tetraacrylate, triethyleneglycol diacrylate, polyethyleneglycol diacrylate, dipentaerythritol hexadiacrylate, dipentaerythritol tridiacrylate, dipentaerythritol diacrylate, sorbitol triacrylate, a bisphenol A diacrylate derivative, dipentaerythritol polyacrylate, and methacrylates thereof.

The photosensitive resin composition may further include a solvent so that a solid content is about 10 parts by weight to about 50 parts by weight of the entire photosensitive resin composition.

In another aspect, a method of forming a pattern includes applying a photosensitive resin composition on a substrate, and exposing and developing the photosensitive resin composition, in which the photosensitive resin composition includes an acryl-based copolymer formed by copolymerizing i) at least one of an unsaturated carboxylic acid, an unsaturated carboxylic acid anhydride, and a mixture thereof and ii) at least one of an olefin-based unsaturated compound and a mixture of olefin-based unsaturated compounds, a photoinitiator represented by the following Chemical Formula 1 or 2, a multifunctional acrylate oligomer, a multifunctional monomer having an ethylenically unsaturated bond, and a melamine crosslinking agent.

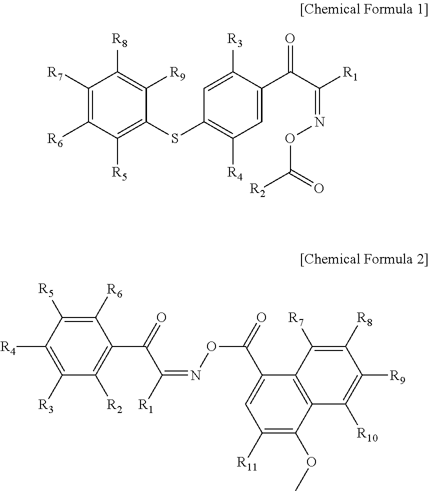

Herein, in Chemical Formula 1 R1 is an alkyl group having 1 to 8 carbon atoms, R2 is a phenyl group or an alkyl group having 1 to 8 carbon atoms, and R3 to R9 are each independently hydrogen, a halogen atom, or an alkyl group having 1 to 8 carbon atoms. In Chemical Formula 2, R1 is an alkyl group having 1 to 8 carbon atoms, and R2 to R11 are each independently hydrogen, a halogen atom, or an alkyl group having 1 to 8 carbon atoms.

The melamine crosslinking agent may be represented by the following Chemical Formula 3.

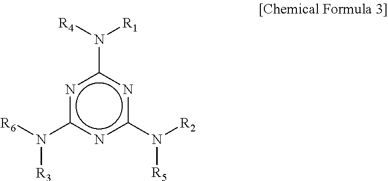

Herein, in Chemical Formula 3, R1, R2, and R3 are each independently —CH₂O (CH₂)ₙCH₃ (n is an integer of 0 to 3), and R4, R5, and R6 are each independently or simultaneously hydrogen, —(CH₂)OH, or —CH₂O (CH₂)ₙCH₃ (n is an integer of 0 to 3).

The photosensitive resin composition may further include a silane coupling agent.

A content of the acryl-based copolymer obtained after 5 parts by weight to 40 parts by weight of the acryl-based copolymer of the at least one of the unsaturated carboxylic acid, the unsaturated carboxylic acid anhydride, and the mixture thereof and 60 parts by weight to 95 parts by weight of the acryl-based copolymer of the acryl-based copolymer the olefin-based unsaturated compound and the mixture of olefin-based unsaturated compounds are copolymerized and an unreacted monomer is removed may be about 100 parts by weight, the content of the photoinitiator may be about 0.1 parts by weight to about 30 parts by weight of the acryl-based copolymer, the content of the multifunctional acrylate oligomer may be about 1 part by weight to about 50 parts by weight of the acryl-based copolymer, the content of the multifunctional monomer having the ethylenically unsaturated bond may be about 1 part by weight to about 50 parts by weight of the acryl-based copolymer, the content of the melamine crosslinking agent may be about 0.1 parts by weight to about 30 parts by weight of the acryl-based copolymer, and the content of the silane coupling agent may be about 0.1 parts by weight to about 30 parts by weight of the acryl-based copolymer.

The photosensitive resin composition may further include a solvent so that a solid content is about 10 parts by weight to about 50 parts by weight of the entire photosensitive resin composition.

According to the exemplary embodiments, it is possible to use a novel photosensitive resin composition having excellent characteristics such as sensitivity, resolution, heat resistance, and adherence while preventing greenish defects in the course of forming a layer structure.

### BRIEF DESCRIPTION OF THE DRAWINGS

FIG. 1 is a top plan view illustrating a display device according to an exemplary embodiment.

FIG. 2 is a cross-sectional view taken along cut lines II-II′ and II′-II″ of FIG. 1.

### DETAILED DESCRIPTION OF THE EMBODIMENTS

Hereinafter, exemplary embodiments will be described in detail with reference to the accompanying drawings. As those skilled in the art would realize, the described embodiments may be modified in various different ways, all without departing from the spirit or scope of the present invention.

In the drawings, the thickness of layers, films, panels, regions, etc., are exaggerated for clarity. It will be understood that when a layer is referred to as being “on” another layer or substrate, it can be directly on the other layer or substrate, or an intervening layer or layers may also be present. Like reference numerals designate like elements throughout the specification.

A photosensitive resin composition according to an exemplary embodiment includes an acryl-based copolymer formed by copolymerizing unsaturated carboxylic acid, unsaturated carboxylic acid anhydride, or a mixture thereof and an olefin-based unsaturated compound or a mixture thereof, a photoinitiator represented by the following Chemical Formula 1 or 2, a multifunctional acrylate oligomer, a multifunctional monomer having an ethylenically unsaturated bond, and a melamine crosslinking agent.

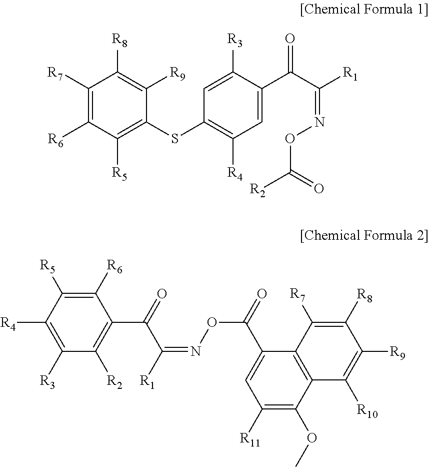

In the present exemplary embodiment, the acryl-based copolymer is an alkali-soluble resin, and may be obtained through synthesis by radical-reacting i) unsaturated carboxylic acid, unsaturated carboxylic acid anhydride, or a mixture thereof, and ii) an olefin-based unsaturated compound or a mixture thereof as monomers in the presence of a solvent and a polymerization initiator, and removing unreacted monomers through precipitation, filtering, and vacuum drying processes.

The acryl-based copolymer used in the present exemplary embodiment serves to easily form a predetermined pattern on which a scum (i.e. a surface layer of froth) does not occur when developing is performed.

In the present exemplary embodiment, the unsaturated carboxylic acid, the unsaturated carboxylic acid anhydride, or the mixture thereof may include at least one selected from the group including acrylic acid, methacrylic acid, maleic acid, fumaric acid, citraconic acid, mesaconic acid, itaconic acid, and anhydrides thereof. Herein, it is more preferable to use the acrylic acid, the methacrylic acid, and maleic acid anhydride in terms of copolymerization reactivity and solubility to an alkali aqueous solution that is a developing solution.

The unsaturated carboxylic acid, the unsaturated carboxylic acid anhydride, or the mixture thereof may be included in the content of 5 parts by weight to 40 parts by weight of the acryl-based copolymer. In the case where the content is less than 5 parts by weight of the acryl-based copolymer, it is difficult to perform dissolving in the alkali aqueous solution, and in the case where the content is more than 40 parts by weight of the acryl-based copolymer, there is a problem in that solubility to the alkali aqueous solution is excessively increased.

In the present exemplary embodiment, the olefin-based unsaturated compound may include at least one selected from the group including methylmethacrylate, ethylmethacrylate, n-butyl methacrylate, sec-butyl methacrylate, tert-butyl methacrylate, methylacrylate, isopropyl acrylate, cyclohexyl methacrylate, 2-methylcyclo hexylmethacrylate, dicyclopentenylacrylate, dicyclopentanylacrylate, dicyclopentenylmethacrylate, dicyclopentanylmethacrylate, 1-adamantyl acrylate, 1-adamantyl methacrylate, dicyclopentanyloxyethylmethacrylate, isoboronylmethacrylate, cyclohexylacrylate, 2-methylcyclohexylacrylate, dicyclopentanyloxyethylacrylate, isoboronylacrylate, phenylmethacrylate, phenylacrylate, benzylacrylate, 2-hydroxyethylmethacrylate, styrene, σ-methyl styrene, m-methyl styrene, p-methyl styrene, vinyltoluene, p-methoxy styrene, 1,3-butadiene, isoprene, 2,3-dimethyl 1,3-butadiene, acrylic acid glycidyl, methacrylic acid glycidyl, α-ethylacrylic acid glycidyl, α-n-propylacrylic acid glycidyl, α-n-butylacrylic acid glycidyl, acrylic acid-β-methylglycidyl, methacrylic acid-β-methylglycidyl, acrylic acid-β-ethylglycidyl, methacrylic acid-β-ethylglycidyl, acrylic acid-3,4-epoxybutyl, methacrylic acid-3,4-epoxybutyl, acrylic acid-6,7-epoxyheptyl, methacrylic acid-6,7-epoxyheptyl, α-ethylacrylic acid-6,7-epoxyheptyl, o-vinylbenzylglycidylether, m-vinylbenzylglycidylether, p-vinylbenzylglycidylether, and methacrylic acid 3,4-epoxycyclohexyl.

Herein, it is useful that the olefin-based unsaturated compound be included in the content of 60 parts by weight to 95 parts by weight of the acryl-based copolymer based on the entire monomers. In the case where the content is less than 60 parts by weight of the acryl-based copolymer, resolution and heat resistance deteriorate, and in the case where the content is more than 95 parts by weight of the acryl-based copolymer, there is a problem in that it is difficult to dissolve the acryl-based copolymer in the alkali aqueous solution that is the developing solution.

A solvent such as methanol, tetrahydroxyfuran, toluene, and/or dioxane may be used in order to perform solution polymerization of monomers constituting the unsaturated carboxylic acid, the unsaturated carboxylic acid anhydride, or the mixture thereof and monomers constituting the olefin-based unsaturated compound. In addition, a radical polymerization initiator such as 2,2-azobisisobutyronitrile, 2,2-azobis(2,4-dimethylvaleronitrile), 2,2-azobis(4-methoxy 2,4-dimethylvaleronitrile), 1,1-azobis(cyclohexane-1-carbonitrile), or dimethyl 2,2′-azobisisobutylate may be used in order to perform solution polymerization of the aforementioned monomers.

It is useful that the polystyrene-converted weight average molecular weight of the acryl-based copolymer obtained by radical reacting the aforementioned monomers under the presence of the solvent and the polymerization initiator, and removing unreacted monomers through the precipitating, filtering, and vacuum drying processes, be about 3,000 to about 30,000. In the case of an organic insulating layer in which the polystyrene-converted weight average molecular weight is less than 3,000, there is a problem in that characteristics such as a developing property and a retention rate deteriorate, or a pattern phenomenon, heat resistance, and the like are reduced. Further, in the case of the organic insulating layer in which the polystyrene-converted weight average molecular weight is more than 30,000, there is a problem in that the pattern phenomenon is reduced.

In the present exemplary embodiment, an oxime-based compound represented by the following Chemical Formula 1 or 2 may be used as the photoinitiator, and the compounds may be used alone or used while two kinds or more thereof are mixed.

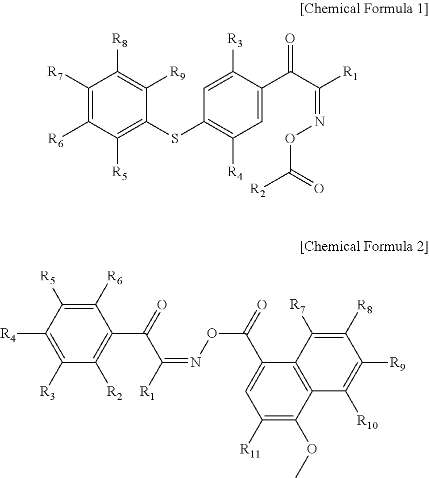

In Chemical Formula 1, R1 is an alkyl group having 1 to 8 carbon atoms, R2 is a phenyl group or an alkyl group having 1 to 8 carbon atoms, and R3 to R9 are each independently hydrogen, a halogen atom, or an alkyl group having 1 to 8 carbon atoms. In Chemical Formula 2, R1 is an alkyl group having 1 to 8 carbon atoms, and R2 to R11 are each independently hydrogen, a halogen atom, or an alkyl group having 1 to 8 carbon atoms.

In the present exemplary embodiment, because the oxime-based compound represented by Chemical Formula 1 or 2 is used, even though the oxime-based compound is exposed to high energy at a short wavelength, formation of a chromophore through decomposition and recombination is prevented. Accordingly, the oxime-based compound serves to prevent the occurrence of greenish defects.

The content of the photoinitiator may include about 0.1 parts by weight to about 30 parts by weight based on 100 parts by weight of the acryl-based copolymer. In the case where the content is less than 0.1 parts by weight, the retention rate deteriorates due to low sensitivity, and in the case where the content is more than 30 parts by weight, there are problems in that the developing property is reduced and the resolution deteriorates.

In the present exemplary embodiment, the multifunctional acrylate oligomer has 2 to 20 functional groups, and an aliphatic urethane acrylate oligomer, an aromatic urethane acrylate oligomer, an epoxy acrylate oligomer, an epoxy methacrylate oligomer, a polyester acrylate oligomer, a silicon acrylate oligomer, a melamine acrylate oligomer, a dendritic acrylate oligomer, and the like may be used, and may be used alone or used with two kinds or more thereof mixed.

It is useful that the content of the multifunctional acrylate oligomer include about 1 parts by weight to about 50 parts by weight based on 100 parts by weight of the acryl-based copolymer. In the case where the content is less than 1 parts by weight of the acryl-based copolymer, the retention rate deteriorates due to low sensitivity, and in the case where the content is more than 50 parts by weight of the acryl-based copolymer, there are problems in that the developing property is reduced and the resolution deteriorates.

In the present exemplary embodiment, as the multifunctional monomer having the ethylenically unsaturated bond, 1,4-butanediol diacrylate, 1,3-butyleneglycol diacrylate, ethyleneglycol diacrylate, trimethylolpropane diacrylate, trimethylolpropanetriacrylate, pentaerythritoltriacrylate, pentaerythritoltetraacrylate, triethyleneglycol diacrylate, polyethyleneglycol diacrylate, dipentaerythritolhexa diacrylate, dipentaerythritoltri diacrylate, dipentaerythritol diacrylate, sorbitoltriacrylate, bisphenol A diacrylate derivative, dipentaerythritolpolyacrylate, and methacrylates thereof, and the like may be used, and may be used alone or used with two kinds or more thereof mixed.

In the present exemplary embodiment, since sensitivity may be increased by using the multifunctional monomer having the ethylenically unsaturated bond, a reduction in reactivity may be compensated by using the oxime-based compound as the photoinitiator.

Herein, it is useful that the content of the multifunctional monomer having the ethylenically unsaturated bond include 1 part by weight to 50 parts by weight based on 100 parts by weight of the acryl-based copolymer. In the case where the content is less than 1 part by weight of the acryl-based copolymer, the retention rate deteriorates due to low sensitivity, and in the case where the content is more than 50 parts by weight of the acryl-based copolymer, there are problems in that the developing property is reduced and the resolution deteriorates.

In the present exemplary embodiment, the melamine crosslinking agent is used to improve adherence with a lower substrate, and any one or a mixture of two kinds or more of the compounds represented by the following Chemical Formula 3 may be used. Herein, it is useful that the content of the melamine crosslinking agent include about 0.1 parts by weight to about 30 parts by weight based on 100 parts by weight of the acryl-based copolymer. In the case where the content is less than 0.1 parts by weight of the acryl-based copolymer, adherence with the lower substrate deteriorates, and in the case where the content is more than 30 parts by weight of the acryl-based copolymer, there are problems in that storage stability and the developing property are reduced and the resolution deteriorates.

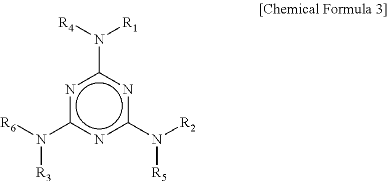

Herein, in Chemical Formula 3, R1, R2, and R3 are each independently —CH₂O(CH₂)ₙCH₃ (n is an integer of 0 to 3), and R4, R5, and R6 are each independently or simultaneously hydrogen, —CH₂OH, or —CH₂O(CH₂)nCH₃ (n is an integer of 0 to 3).

In the present exemplary embodiment, the silane coupling agent is used to improve adherence with a lower substrate, and may include at least one selected from the group including (3-glycideoxypropyl)trimethoxysilane, (3-glycideoxypropyl)triethoxysilane, (3-glycideoxypropyl)methyldimethoxysilane, (3-glycideoxypropyl)methyldiethoxysilane, (3-glycideoxypropyl))dimethylethoxysilane, 3,4-epoxybutyltrimethoxysilane, 3,4-epoxybutyltriethoxysilane, 2-(3,4-epoxycyclohexyl)ethyltrimethoxysilane, 2-(3,4-epoxycyclohexyl)ethyltriethoxysilane, aminopropyltrimethoxysilane, aminopropyltriethoxysilane, 3-triethoxysili-N-(1,3dimethyl-butylidene)propylamine, N-2(aminoethyl)3-aminopropyltrimethoxysilane, N-2(aminoethyl)3-aminopropyltriethoxysilane, N-2(aminoethyl)3-aminopropylmethyldimethoxysilane, N-phenyl-3-aminopropyltrimethoxysilane, and (3-isocyanatepropyl)triethoxysilane.

Herein, it is used that the content of the silane coupling agent include about 0.1 parts by weight to about 30 parts by weight based on 100 parts by weight of the acryl-based copolymer. In the case where the content is less than 0.1 parts by weight of the acryl-based copolymer, adherence with the lower substrate deteriorates, and in the case where the content is more than 30 parts by weight of the acryl-based copolymer, there are problems in that storage stability and the developing property are reduced and the resolution deteriorates.

In the present exemplary embodiment, it is useful that the silane coupling agent be used together with the melamine crosslinking agent. There is an effect that a reaction occurs between the silane coupling agent and the melamine crosslinking agent that further improves characteristics such as adherence with the lower substrate.

Further, a surfactant may be used in order to improve a coating property or the developing property of the photosensitive resin composition. Silicons, fluorines, or the like may be used as the surfactant, and it is useful that the content of the surfactant be about 0.0001 parts by weight to about 2 parts by weight based on 100 parts by weight of the solid.

Meanwhile, according to the exemplary embodiment, a photosensitive resin composition coating solution is provided by adding a solvent to the aforementioned photosensitive resin composition including the acryl-based copolymer, the photoinitiator, the multifunctional acrylate oligomer, the multifunctional monomer having the ethylenically unsaturated bond, the melamine crosslinking agent, and the silane coupling agent.

The solvent included in the photosensitive resin composition coating solution prevents occurrence of flatness of the organic insulating layer and coating stains to form a uniform pattern profile. Herein, as the solvent, alcohols such as methanol and ethanol; ethers such as tetrahydrofuran; glycolethers such as ethyleneglycolmonomethylether and ethyleneglycolmonoethylether; ethyleneglycolalkylether acetates such as methylcellosolve acetate and ethylcellosolve acetate; diethyleneglycols such as diethyleneglycolmonomethylether, diethyleneglycolmonoethylether, and diethyleneglycoldimethylether; propyleneglycolmonoalkylethers such as propyleneglycolmethylether, propyleneglycolethylether, propyleneglycolpropylether, and propyleneglycolbutylether; propyleneglycolalkylether acetates such as propyleneglycolmethylether acetate, propyleneglycolethylether acetate, propyleneglycolpropylether acetate, and propyleneglycolbutylether acetate; propyleneglycolalkylether acetates such as propyleneglycolmethylether propionate, propyleneglycolethylether propionate, propyleneglycolpropylether propionate, and propyleneglycolbutylether propionate; aromatic hydrocarbons such as toluene and xylene; ketones such as methylethylketone, cyclohexanone, and 4-hydroxy 4-methyl 2-pentanone; esters such as methyl acetate, ethyl acetate, propyl acetate, butyl acetate, ethyl 2-hydroxypropionate, methyl 2-hydroxy2-methylpropionate, ethyl 2-hydroxy2-methylpropionate, methyl hydroxyacetate, ethyl hydroxyacetate, butyl hydroxyacetate, methyl sulfate, ethyl sulfate, propyl sulfate, butyl sulfate, methyl 3-hydroxypropionate, ethyl 3-hydroxypropionate, propyl 3-hydroxypropionate, butyl 3-hydroxypropionate, methyl 2-hydroxy-3-methylbutanate, methyl methoxyacetate, ethyl methoxyacetate, propyl methoxyacetate, butyl methoxyacetate, methyl ethoxyacetate, ethyl ethoxyacetate, propyl ethoxyacetate, butyl ethoxyacetate, methyl propoxyacetate, ethyl propoxyacetate, propyl propoxyacetate, butyl propoxyacetate, methyl butoxyacetate, ethyl butoxyacetate, propyl butoxyacetate, butyl butoxyacetate, methyl 2-methoxypropionate, ethyl 2-methoxypropionate, propyl 2-methoxypropionate, butyl 2-methoxypropionate, methyl 2-ethoxypropionate, ethyl 2-ethoxypropionate, propyl 2-ethoxypropionate, butyl 2-ethoxypropionate, methyl 2-butoxypropionate, ethyl 2-butoxypropionate, propyl 2-butoxypropionate, butyl 2-butoxypropionate, methyl 3-methoxypropionate ethyl 3-methoxypropionate, propyl 3-methoxypropionate, methyl 3-ethoxypropionate, ethyl 3-ethoxypropionate, propyl 3-ethoxypropionate, butyl 3-ethoxypropionate, methyl 3-propoxypropionate, ethyl 3-propoxypropionate, propyl 3-propoxypropionate, butyl 3-propoxypropionate, methyl 3-butoxypropionate, ethyl 3-butoxypropionate, propyl 3-butoxypropionate, and butyl 3-butoxypropionate, and the like may be used, and may be used with one kind or more thereof mixed if necessary.

Particularly, it is useful to use the solvent by selecting one kind or more from the group consisting of glycolethers, ethylenealkylether acetates and diethyleneglycols, which have excellent solubility and reactivity to each component and easily form a coating layer.

It is useful that the solvent be included so that the content of the solid of the components included in the entire photosensitive resin composition is about 10 wt % to about 50 wt %, and it is useful that the composition having the solid in the aforementioned range be used after being filtered by a millipore filter of 0.1 um to 0.2 um or the like. More preferably, the solvent may be included so that the content of the solid of the components included in the entire photosensitive resin composition is about 15 wt % to about 40 wt %. In the case where the content of the solid of the entire photosensitive resin composition is less than 10 wt %, there are problems in that a coating thickness is reduced and coating flatness deteriorates, and in the case where the content is more than 50 wt %, there are problems in that the coating thickness is increased and coating equipment is under strain during coating.

### Synthetic Example 1

### Manufacturing of the Acryl-Based Copolymer

The mixed solution of 400 parts by weight of tetrahydrofuran, 30 parts by weight of the methacrylic acid, 30 parts by weight of styrene, and 40 parts by weight of glycidyl methacrylate was added to the flask having the cooler and the agitator. After the liquid composition was sufficiently mixed in the mixing vessel at 600 rpm, 15 parts by weight of 2,2′-azobis(2,4-dimethylvaleronitrile) was added. The polymerization mixing solution was slowly increased to 55° C., maintained at this temperature for 24 hours, and cooled to room temperature, and 500 ppm of hydrobenzophenone was added as the polymerization inhibitor to obtain a polymer solution having a solid concentration of 30 wt %.

100 parts by weight of the polymer solution was precipitated based on 1000 parts by weight of n-hexane in order to remove the unreacted monomers of the polymer solution. After precipitation, the poor solvent in which the unreactant was dissolved was removed through the filtering process using the mesh. Thereafter, the solvents were completely removed through the vacuum drying process at 30° C. or lower in order to remove the solvents containing the unreacted monomers remaining even after the filtering process, thus manufacturing the acryl-based copolymer.

The weight average molecular weight of the acryl-based copolymer was 6,000. In this case, the weight average molecular weight was the polystyrene-converted average molecular weight measured by using the GPC (gel permeation chromatography).

### Example 1

### Manufacturing of the Negative Photosensitive Resin Composition

100 parts by weight of the acryl-based copolymer solution manufactured in Synthetic Example 1, 20 parts by weight of the photoinitiator represented by the following Chemical Formula 4, 5 parts by weight of the 10-functional urethane acrylate oligomer, 20 parts by weight of dipentaerythritol hexaacrylate as the multifunctional monomer having the ethylenically unsaturated bond, 3 parts by weight of the melamine crosslinking agent represented by the following Chemical Formula 5, and 2 parts by weight of (3-glycideoxypropyl)methyldiethoxysilane as the silane coupling agent were mixed. The mixture was dissolved by adding propyleneglycolmonoethyl acetate to the mixture so that the concentration of the solid was 20 wt %, and then filtered by the millipore filter of 0.2 um to manufacture the photosensitive resin composition coating solution.

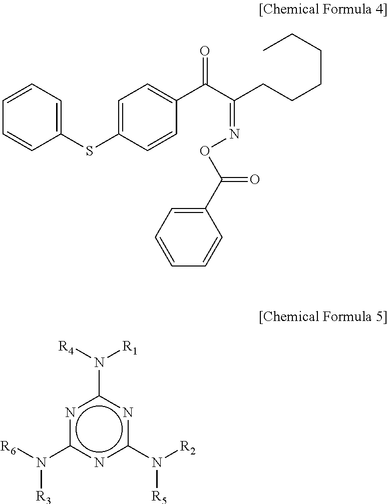

Herein, in Chemical Formula 5, R₁, R₂, R₃, R₄, R₅, and R₆ each independently represent —CH₂OCH₃ in Chemical Formula 5.

### Example 2

### Manufacturing of the Negative Photosensitive Resin Composition

The photosensitive resin composition coating solution was manufactured by the same method as Example 1, except that the photoinitiator represented by the following Chemical Formula 6 was used instead of Chemical Formula 4 that was the photoinitiator in Example 1.

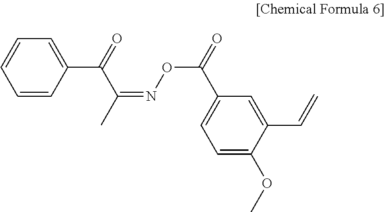 [SMILES: C=Cc1cc(C(=O)O/N=C(/C)C(=O)c2ccccc2)ccc1OC]

### Example 3

### Manufacturing of the Negative Photosensitive Resin Composition

The photosensitive resin composition coating solution was manufactured by the same method as Example 1, except that the photoinitiator represented by the following Chemical Formula 7 was used instead of Chemical Formula 4 that was the photoinitiator in Example 1.

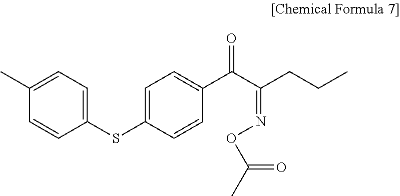 [SMILES: CCC/C(=N/OC(C)=O)C(=O)c1ccc(Sc2ccc(C)cc2)cc1]

### Example 4

### Manufacturing of the Negative Photosensitive Resin Composition

The photosensitive resin composition coating solution was manufactured by the same method as Example 1, except that the photoinitiator represented by the following Chemical Formula 8 was used instead of Chemical Formula 4 that was the photoinitiator in Example 1.

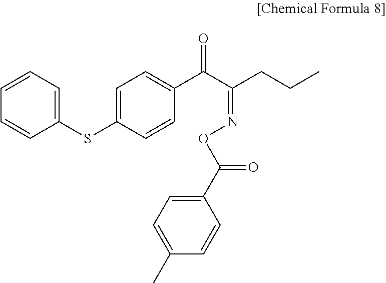 [SMILES: CCC/C(=N/OC(=O)c1ccc(C)cc1)C(=O)c1ccc(Sc2ccccc2)cc1]

### Example 5

### Manufacturing of the Negative Photosensitive Resin Composition

The photosensitive resin composition coating solution was manufactured by the same method as Example 1, except that pentaerythritol triacrylate was used instead of dipentaerythritol hexaacrylate as the multifunctional monomer having the ethylenically unsaturated bond in Example 1.

### Example 6

### Manufacturing of the Negative Photosensitive Resin Composition

The photosensitive resin composition coating solution was manufactured by the same method as Example 1, except that pentaerythritol diacrylate was used instead of dipentaerythritol hexaacrylate as the multifunctional monomer having the ethylenically unsaturated bond in Example 1.

### Example 7

### Manufacturing of the Negative Photosensitive Resin Composition

The photosensitive resin composition coating solution was manufactured by the same method as Example 1, except that dipentaerythritol hexaacrylate was used in the amount of 30 parts by weight instead of 20 parts by weight as the multifunctional monomer having the ethylenically unsaturated bond in Example 1.

### Comparative Example 1

### Manufacturing of the Negative Photosensitive Resin Composition

The photosensitive resin composition coating solution was manufactured by the same method as Example 1, except that the photoinitiator represented by the following Chemical Formula 9 was used instead of Chemical Formula 4 that was the photoinitiator in Example 1.

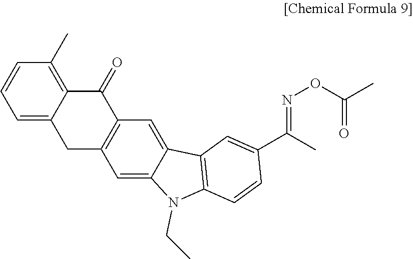 [SMILES: CCn1c2ccc(/C(C)=N/OC(C)=O)cc2c2cc3c(cc21)Cc1cccc(C)c1C3=O]

### Comparative Example 2

### Manufacturing of the Negative Photosensitive Resin Composition

The photosensitive resin composition coating solution was manufactured by the same method as Example 1, except that the melamine crosslinking agent represented by Chemical Formula 5 and (3-glycideoxypropyl)methyldiethoxysilane used as the silane coupling agent in Example 1 were completely removed.

### Comparative Example 3

### Manufacturing of the Negative Photosensitive Resin Composition

The photosensitive resin composition coating solution was manufactured by the same method as Example 1, except that the melamine crosslinking agent represented by Chemical Formula 5 was completely removed.

### Comparative Example 4

### Manufacturing of the Negative Photosensitive Resin Composition

The photosensitive resin composition coating solution was manufactured by the same method as Example 1, except that the (3-glycideoxypropyl)methyldiethoxysilane that used as the silane coupling agent in Example 1 was completely removed.

### Comparative Example 5

### Manufacturing of the Negative Photosensitive Resin Composition

The photosensitive resin composition coating solution was manufactured by the same method as Example 1, except that ten functional urethane acrylate oligomers were completely removed.

### Comparative Example 6

### Manufacturing of the Negative Photosensitive Resin Composition

The photosensitive resin composition coating solution was manufactured by the same method as Example 1, except that the dipentaerythritol hexaacrylate that was used as the multifunctional monomer having the ethylenically unsaturated bond in Example 1 was completely removed.

The physical properties of the photosensitive resin composition coating solutions manufactured in Examples 1 to 7 and Comparative Examples 1 to 6 were evaluated by the following methods. Results thereof are described in the following [Table 1].

A) Sensitivity—The negative photosensitive composition solutions manufactured in Examples 1 to 7 and Comparative Examples 1 to 4 were applied on the glass substrate on which SiNx was deposited by using the spin coater, and pre-baked on the hot plate at 100° C. for 2 mins to form a layer of 3.4 um thick.

Ultraviolet rays having the intensity of 10 mW/cm² at 365 nm were radiated on the obtained layer by using a predetermined pattern mask by using the broadband light exposer for 1 seconds to 5 seconds at an interval of 0.2 sec. Thereafter, developing was performed by the aqueous solution of 2.50 wt % of tetramethylammonium hydroxide at 23° C. for 50 seconds, and washing was performed by ultra-pure water for 60 seconds.

Heating was performed in the oven at 220° C. for 60 minutes for final curing to obtain a pattern layer. Sensitivity was measured by using the SEM (scanning electron microscope) based on the exposure amount at which the retention rate was saturated according to the 20 um Line & Space CD (critical dimension) standard.

B) Limiting resolution—Measurement was performed with respect to the minimum size based on the contact hole of the pattern layer formed when the sensitivity of A) was measured. However, the limiting resolution was represented only when CD Biases were the same as each other.

C) Contact hole scum—Scum was examined based on the contact hole of the pattern layer formed when the sensitivity of A) was measured. The case where the scum was free was represented by ◯, and the case where the scum was observed was represented by x.

D) Adherence—The case where the minimum retention layer of the pattern layer formed when the sensitivity of A) was measured was less than 0.5 μm was represented by ◯, the case where the minimum retention layer was 0.5 to 1.5 μm was represented by Δ, and the case where the minimum retention layer was 1.5 μm or more was represented by x.

E) Transmittance—Evaluation of transparency was performed by measuring transmittance of the pattern layer formed when the sensitivity of A) was measured at 400 nm of the pattern layer by using the spectrophotometer. In this case, the case where transmittance was 93% or more was represented by ◯, the case where transmittance was 90 to 93% was represented by Δ, the case where transmittance was less than 90% was represented by x. However, when transmittance was measured, bare glass was used as the substrate.

F) Greenish—The color coordinate was measured by further radiating near UV radiation of 10 J/cm² based on 365 nm on the measured substrate when transparency was evaluated in E) by using the iron halide metal lamp used in a sealant curing process and having a main wavelength of 200 to 450 nm. As a change rate is increased before and after the near UV is radiated, the color coordinate is green shifted, and thus greenish defects may occur on the final panel. In this case, the case where the change rate was less than 10% was represented by ◯, the case where the change rate was 10 to 30% was represented by Δ, and the case where the change rate was more than 30% was represented by x.

G) Contrast ratio—Luminance (white) and luminance (black) of the measured substrate when transparency was evaluated in E) were measured after the substrate was interposed between normally white mode polarizers by using a contrast tester (model: CT-1), thus measuring the contrast ratio as a ratio of luminance (white)/luminance (black). In this case, the case where the contrast ratio value was 22000 or more was represented by ◯, the case where the contrast ratio value was 20000 to 22000 was represented by Δ, and the case where the contrast ratio value was less than 20000 was represented by x.

TABLE 1

| | | | Contact | | | | |
|---|---|---|---|---|---|---|---|
| | | Limiting | Hole | | | | |
| | | resolution | Scum | | | | Contrast |
| | Sensitivity | (ml/cm2) | (μm) | Adherence | Transmittance | Greenish | Ratio |
| Example 1 | 40 | 6 | ◯ | ◯ | ◯ | ◯ | ◯ |
| Example 2 | 39 | 6 | ◯ | ◯ | ◯ | ◯ | ◯ |
| Example 3 | 41 | 6 | ◯ | ◯ | ◯ | ◯ | ◯ |
| Example 4 | 40 | 6 | ◯ | ◯ | ◯ | ◯ | ◯ |
| Example 5 | 40 | 6 | ◯ | ◯ | ◯ | ◯ | ◯ |
| Example 6 | 41 | 6 | ◯ | ◯ | ◯ | ◯ | ◯ |
| Example 7 | 38 | 6 | ◯ | ◯ | ◯ | ◯ | ◯ |
| Comparative | 40 | 6 | X | ◯ | X | X | X |
| Example 1 | | | | | | | |
| Comparative | 41 | 8 | ◯ | X | ◯ | ◯ | ◯ |
| Example 2 | | | | | | | |
| Comparative | 41 | 6 | ◯ | X | ◯ | ◯ | ◯ |
| Example 3 | | | | | | | |
| Comparative | 38 | 6 | ◯ | X | ◯ | ◯ | ◯ |
| Example 4 | | | | | | | |
| Comparative | 55 | 6 | ◯ | X | ◯ | ◯ | ◯ |
| Example 5 | | | | | | | |
| Comparative | 60 | 6 | ◯ | X | ◯ | ◯ | ◯ |
| Example 6 | | | | | | | |

Referring to Table 1, Examples 1 to 7 manufactured to include the photosensitizer represented by Chemical Formula 1 according to exemplary embodiments have excellent resolution, transmittance, lack of greenish color, contrast ratio, and lack of contact hole scum characteristics as compared to Comparative Example 1. Further, it could be confirmed that adherence was excellent as compared to Comparative Examples 2 to 6. Further, it could be confirmed that sensitivity was excellent as compared to Comparative Examples 5 and 6.

Thereby, it can be confirmed that the negative type photosensitive resin composition according to exemplary embodiments has excellent sensitivity, resolution, transmittance, chemical resistance, process margin, and the like, particularly, is free of contact hole scum, has excellent adherence and contrast ratio, and has an excellent greenish characteristic to UV during seal curing, and thus is a negative photosensitive resin composition suitable to be used in a high luminance and narrow bezel display.

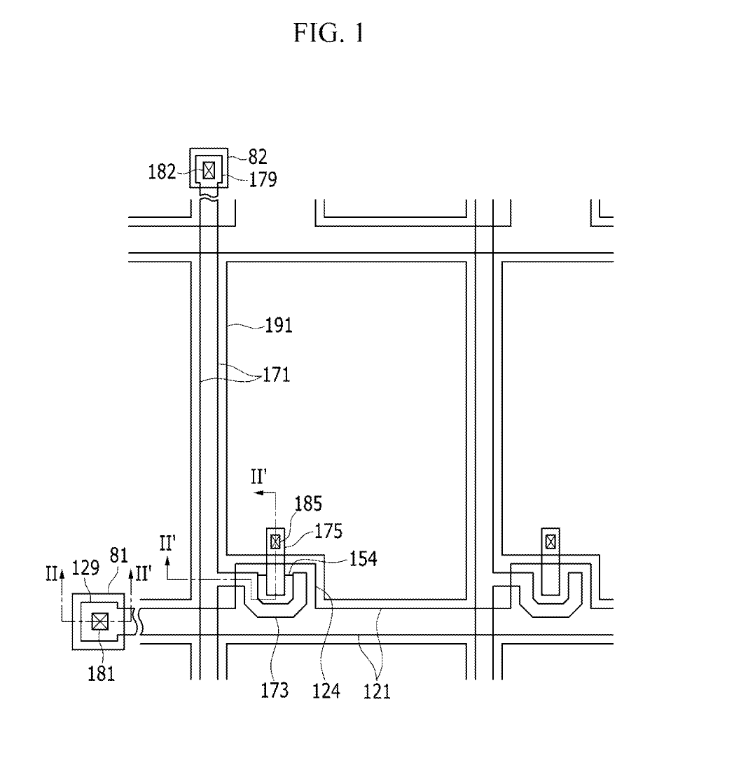

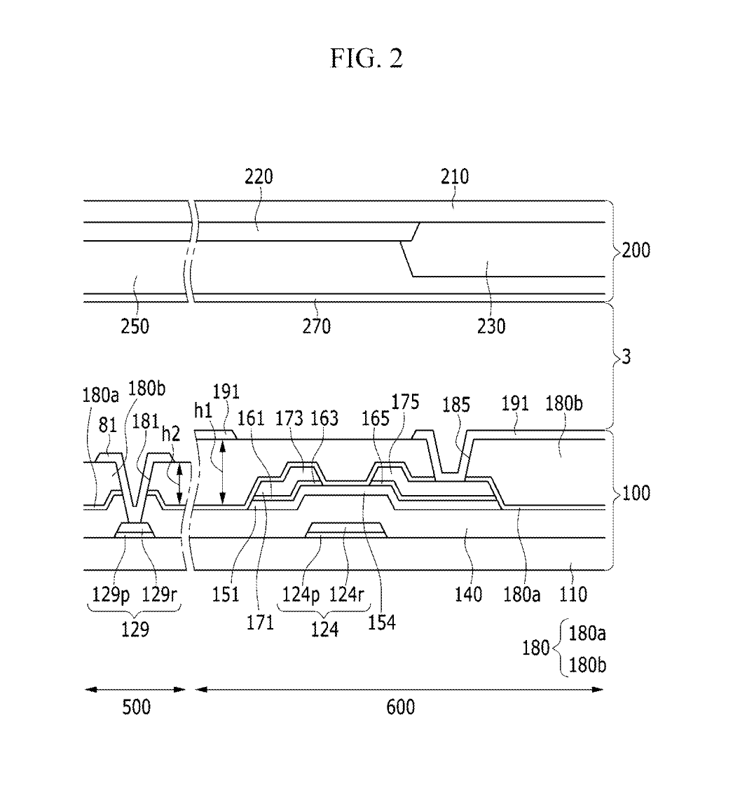

Hereinafter, the display device including an organic layer using the photosensitive resin composition according to exemplary embodiments and a method of forming an organic layer pattern will be described with reference to FIGS. 1 and 2.

FIG. 1 is a top plan view illustrating the display device according to an exemplary embodiment. FIG. 2 is a cross-sectional view taken along cut lines II-II′ and II′-II″ of FIG. 1.

Referring to FIG. 1 and FIG. 2, the display device according to an exemplary embodiment includes a lower panel 100 and an upper panel 200, and a liquid crystal layer 3 interposed between two display panels 100 and 200.

First, the lower panel 100 will be described.

A plurality of gate lines 121 is formed on an insulation substrate 110, which is made of transparent glass or plastics.

The gate line 121 transfers a gate signal and mainly extends in a horizontal direction. Each gate line 121 includes a plurality of gate electrodes 124 that protrude from the gate line 121 and a wide end portion 129 for connection with another layer or a gate driver (not illustrated). The end portion 129 of the gate line may be formed of a dual-layer that includes a lower layer 129p and an upper layer 129r.

The gate line 121 and the gate electrode 124 have a dual-layer structure formed of lower layers 121p and 124p and upper layers 121r and 124r. The lower layers 121p and 124p may be formed, for example, of any one of titanium, tantalum, molybdenum, and alloys thereof, and the upper layers 121r and 124r may be formed, for example, of copper (Cu) or a copper alloy. In the present exemplary embodiment, it is described that the gate line 121 and the gate electrode 124 have the dual-layer structure, but the gate line 121 and the gate electrode 124 may have a single-layered structure.

A gate insulating layer 140 made of an insulating material such as, for example, silicon nitride or silicon oxide is formed on the gate line 121.

A semiconductor layer 151 made of, for example, hydrogenated amorphous silicon, polysilicon, or the like is formed on the gate insulating layer 140. The semiconductor layer 151 mainly extends in a vertical direction (FIG. 1), and includes a plurality of projections 154 extending toward the gate electrode 124.

A plurality of ohmic contact stripes 161 and ohmic contact islands 165 are formed on the projection 154 of the semiconductor layer 151. The ohmic contact stripe 161 has a plurality of projections 163, and the projections 163 and the ohmic contact island 165 form a pair and are disposed on the projection 154 of the semiconductor layer 151.

A plurality of data lines 171, a plurality of source electrodes 173 connected to a plurality of data lines 171, and a plurality of drain electrodes 175 facing the source electrodes 173 are formed on the ohmic contacts 161 and 165 and the gate insulating layer 140.

The data line 171 transports a data signal and mainly extends in a vertical direction to cross the gate line 121. The source electrode 173 may extend toward the gate electrode 124 to have a U shape, but this is just an example, and the source electrode may have variously modified shapes.

The drain electrode 175 is separated from the data line 171, and extends upwardly from the middle of the U-shaped source electrode 173. The data line 171 includes an end portion 179 having a wide area for connection with another layer or a data driver (not illustrated).

Although not illustrated, the data line 171, the source electrode 173, and the drain electrode 175 may have a dual-layer structure of an upper layer and a lower layer. The upper layer may be formed, for example, of copper (Cu) or a copper alloy, and the lower layer may be formed, for example, of any one of titanium (Ti), tantalum (Ta), molybdenum (Mo), and alloys thereof.

The data line 171, the source electrode 173, and the drain electrode 175 may have a tapered lateral surface.

The ohmic contacts 161, 163, and 165 exist only between the semiconductors layers 151 and 154 therebeneath and the data line 171 and the drain electrode 175 thereon, and reduce contact resistance therebetween. Further, the ohmic contacts 161, 163, and 165 may have substantially the same plane pattern as the data line 171, the source electrode 173, and the drain electrode 175.

In the projection 154 of the semiconductor layer 151, there is an exposed portion that is not covered by the data line 171 and drain electrode 175, such as a portion between the source electrode 173 and drain electrode 175. The semiconductor layer 151 has substantially the same plane pattern as the ohmic contacts 161 and 165 except for the exposed portion of the projection 154.

One gate electrode 124, one source electrode 173, and one drain electrode 175 form one thin film transistor (TFT) together with the projection 154 of the semiconductor layer 151, and the channel of the thin film transistor is formed in the projection 154 between the source electrode 173 and drain electrode 175.

A passivation layer 180 including a first passivation layer 180a and a second passivation layer 180b is formed on the data line 171, the drain electrode 175, and the exposed portion of the projection 154 of the semiconductor layer. The first passivation layer 180a may be formed of an inorganic insulating layer such as, for example, silicon nitride or silicon oxide, and the second passivation layer 180b may be formed of the photosensitive resin composition disclosed herein according to an exemplary embodiment. The first passivation layer 180a may be omitted.

The second passivation layer 180b may be mostly thickly formed in a portion adjacent to the thin film transistor portion 600, and may be relatively thinly formed in a pad portion 500. A first thickness h1 representing a thickness of the second passivation layer 180b in the portion adjacent to the thin film transistor portion 600 is larger than the thickness of the second passivation layer 180b in the pad portion 500. The first thickness h1 needs to be large in order to reduce parasitic capacitance between the data line 171 and the pixel electrode 191, and the second thickness h2 needs to be small in order to form the contact hole 181.

Likewise, if the second passivation layer 180b is thinly formed in the pad portion 500, adherence to the lower layer may be weakened, and if the second passivation layer 180b is thickly formed in the thin film transistor portion 600, resolution needs to be significantly increased in order to form the contact hole 185 having the small size. Accordingly, a photosensitive resin that can complement these properties should be used. The photosensitive resin composition according to the exemplary embodiments reinforces adherence, and at the same time, has a property of high resolution, and thus an organic insulating layer having excellent characteristics may be formed.

A halftone mask may be used in order to thinly form the second passivation layer 180b in the pad portion 500.

A contact hole 181 through which an end portion 129 of the gate line 121 is exposed is formed in the passivation layer 180 and the gate insulating layer 140. Further, a contact hole 182 through which an end portion 179 of the data line 171 is exposed and a contact hole 185 through which an end of the drain electrode 175 is exposed are formed in the passivation layer 180.

The second passivation layer 180b formed of the organic insulating layer may be patterned through exposure and developing processes and the like. Specifically, the second passivation layer 180b is obtained by applying the photosensitive resin composition disclosed herein according to an exemplary embodiment on the substrate 110 or the first passivation layer 180a by a spray method, a roll coater method, a rotation coating method, or the like, and removing a solvent by pre-baking to form a coat layer. In this case, it is preferable that the pre-baking be performed at a temperature of 80° C. to 120° C. for 1 minute to 5 minutes.

Next, a predetermined pattern is formed by radiating visible rays, ultraviolet rays, far-ultraviolet rays, electronic beams, X-rays, or the like on the formed coat layer according to a previously prepared pattern, and developing the coat layer by a developing solution to remove an unnecessary portion.

Herein, it is useful to use an alkali aqueous solution as the developing solution, and specifically, aqueous solutions of inorganic alkalis such as sodium hydroxide, potassium hydroxide, and sodium carbonate, primary amines such as ethylamine and n-propylamine, secondary amines such as diethylamine and n-propylamine, tertiary amines such as trimethylamine, methyldiethylamine, dimethylethylamine, and triethylamine, alcohol amines such as dimethylethanol amine, methyldiethanol amine, and triethanol amine, quaternary ammonium salts such as tetramethylammonium hydroxide and tetraethylammonium hydroxide may be used. In this case, the developing solution is used by dissolving an alkali compound in a concentration of 0.1 to 10 parts by weight of the alkali aqueous solution, and a water-soluble organic solvent such as methanol and ethanol, and a surfactant may be added in an appropriate amount.

Further, after developing is performed by the aforementioned developing solution, washing may be performed by ultra-pure water for 50 seconds to 180 seconds to remove an unnecessary portion, drying may be performed to form a pattern, rays such as ultraviolet rays may be radiated on the formed pattern, and the pattern may be subjected to heating treatment by a heating device such as an oven at a temperature of 150° C. to 250° C. for 30 minutes to 90 minutes to obtain a final pattern.

A pixel electrode 191 and contact assistants 81 and 82 are formed on the passivation layer 180. They may be made of a transparent conductive material such as ITO or IZO, or reflective metal such as aluminum, silver, chromium or an alloy thereof.

The pixel electrode 191 is physically electrically connected to the drain electrode 175 through the contact hole 185, and receives a data voltage from the drain electrode 175.

The contact assistants 81 and 82 are connected through the contact holes 181 and 182 to the end portion 129 of the gate line 121 and the end portion 179 of the data line 171, respectively. The contact assistants 81 and 82 complement adherence between the end portion 129 of the gate line 121 and the end portion 179 of the data line 171 and an external device, and protect the end portions.

Next, the upper panel 200 will be described.

A light blocking member 220 is formed on an insulation substrate 210 made of transparent glass, plastics, or the like. The light blocking member 220 prevents light leakage between the pixel electrodes 191 and defines an opening region facing the pixel electrode 191.

A plurality of color filters 230 is formed on the insulation substrate 210 and the light blocking member 220. The color filter 230 may be mainly present in the region surrounded by the light blocking member 220, and may longitudinally extend along a column of the pixel electrodes 191. Each color filter 230 may display any one of three primary colors of red, green, and blue colors.

In the present exemplary embodiment, it is described that the light blocking member 220 and the color filter 230 are formed in the upper panel 200, but at least one of the light blocking member 220 and the color filter 230 may be formed in the lower panel 100.

An overcoat 250 is formed on the color filter 230 and the light blocking member 220. The overcoat 250 may be made of an (organic) insulator, and prevents exposure of the color filter 230 and provides a flat surface. The overcoat 250 may be omitted.

A common electrode 270 is formed on the overcoat 250. The common electrode 270 is made of a transparent conductor such as, for example, ITO or IZO, and receives a common voltage Vcom.

The liquid crystal layer 3 that is interposed between the lower panel 100 and the upper panel 200 includes liquid crystal molecules that may have a negative dielectric anisotropy, and the liquid crystal molecules may be aligned so that long axes thereof are vertical in respects to the surfaces of two panels 100 and 200 in a state in which there is no electric field.

The pixel electrode 191 and the common electrode 270 form a liquid crystal capacitor together with a portion of the liquid crystal layer 3 therebetween to maintain the applied voltage even after the thin film transistor is turned off.

The pixel electrode 191 may form a storage capacitor by overlapping with the storage electrode line (not illustrated), and a voltage maintaining ability of the liquid crystal capacitor may be increased therethrough.

The exemplary embodiment disclosed herein used the photosensitive film resin composition according to the exemplary embodiments in the organic insulating layer of the liquid crystal display, but the photosensitive film resin according to the exemplary embodiments can be applied to all display devices the include an organic insulating layer, such as an organic light emitting device.

While the disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the disclosure, including appended claims.

### DESCRIPTION OF SYMBOLS

| | | | |
|---|---|---|---|
| 124 | Gate electrode | 140 | Gate insulating layer |
| 173 | Source electrode | 175 | Drain electrode |
| 180a | First passivation layer | 180b | Second passivation layer |

What is claimed is:

1. A photosensitive resin composition comprising:
an acryl-based copolymer formed by copolymerizing i) at least one of an unsaturated carboxylic acid, an unsaturated carboxylic acid anhydride, and a mixture thereof and ii) at least one of an olefin-based unsaturated compound or a mixture of olefin-based unsaturated compounds,
a photoinitiator represented by the following Chemical Formula 1 or 2,
a multifunctional acrylate oligomer,
a multifunctional monomer having an ethylenically unsaturated bond, and
a melamine crosslinking agent: 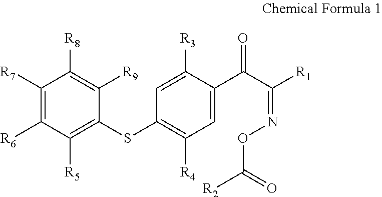
wherein, in Chemical Formula 1, R1 is an alkyl group having 1 to 8 carbon atoms, R2 is a phenyl group or an alkyl group having 1 to 8 carbon atoms, and R3 to R9 are each independently hydrogen, a halogen atom, or an alkyl group having 1 to 8 carbon atoms, and 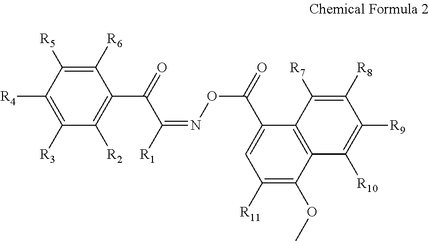
wherein in Chemical Formula 2, R1 is an alkyl group having 1 to 8 carbon atoms, and R2 to R11 are each independently hydrogen, a halogen atom, or an alkyl group having 1 to 8 carbon atoms.

2. The photosensitive resin composition of claim 1, wherein:
the melamine crosslinking agent is represented by the following Chemical Formula 3: 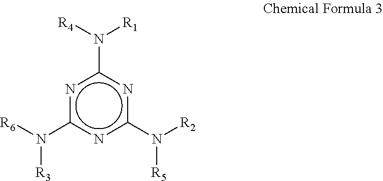
wherein in Chemical Formula 3, R1, R2, and R3 are each independently —CH₂O (CH₂)ₙCH₃ (n is an integer of 0 to 3), and R4, R5, and R6 are each independently or simultaneously hydrogen, —(CH₂)OH, or —CH₂O (CH₂)ₙCH₃ (n is an integer of 0 to 3).

3. The photosensitive resin composition of claim 1, further comprising:
a silane coupling agent.

4. The photosensitive resin composition of claim 3, wherein:
the silane coupling agent includes at least one selected from the group including (3-glycideoxypropyl)trimethoxysilane, (3-glycideoxypropyl)triethoxysilane, (3-glycideoxypropyl)methyldimethoxysilane, (3-glycideoxypropyl)methyldiethoxysilane, (3-glycideoxypropyl)dimethylethoxysilane, 3,4-epoxybutyltrimethoxysilane, 3,4-epoxybutyltriethoxysilane, 2-(3,4-epoxycyclohexyl)ethyltrimethoxysilane, 2-(3,4-epoxycyclohexyl)ethyltriethoxysilane, aminopropyltrimethoxysilane, aminopropyltriethoxysilane, 3-triethoxysili-N-(1,3dimethyl-butylidene)propylamine, N-2(aminoethyl)3-aminopropyltrimethoxysilane, N-2(aminoethyl)3-aminopropyltriethoxysilane, N-2(aminoethyl)3-aminopropylmethyldimethoxysilane, N-phenyl-3-aminopropyltrimethoxysilane, and (3-isocyanatepropyl)triethoxysilane.

5. The photosensitive resin composition of claim 4, wherein:
a content of the acryl-based copolymer obtained after 5 parts by weight to 40 parts by weight of the acryl-based copolymer of the at least one of the unsaturated carboxylic acid, the unsaturated carboxylic acid anhydride, and the mixture thereof, and 60 parts by weight to 95 parts by weight of the acryl-based copolymer of the at least one of the olefin-based unsaturated compound and the mixture olefin-based unsaturated compounds are copolymerized and an unreacted monomer is removed is about 100 parts by weight,
the content of the photoinitiator is about 0.1 parts by weight to about 30 parts by weight of the acryl-based copolymer,
the content of the multifunctional acrylate oligomer is about 1 part by weight to about 50 parts by weight of the acryl-based copolymer,
the content of the multifunctional monomer having the ethylenically unsaturated bond is about 1 part by weight to about 50 parts by weight of the acryl-based copolymer,
the content of the melamine crosslinking agent is about 0.1 parts by weight to about 30 parts by weight of the acryl-based copolymer, and
the content of the silane coupling agent is about 0.1 parts by weight to about 30 parts by weight of the acryl-based copolymer.

6. The photosensitive resin composition of claim 1, wherein:
the unsaturated carboxylic acid, the unsaturated carboxylic acid anhydride, or the mixture thereof includes at least one selected from the group including acrylic acid, methacrylic acid, maleic acid, fumaric acid, citraconic acid, mesaconic acid, itaconic acid, and anhydrides thereof.

7. The photosensitive resin composition of claim 1, wherein:
the olefin-based unsaturated compound includes at least one selected from the group including methylmethacrylate, ethylmethacrylate, n-butyl methacrylate, sec-butyl methacrylate, tert-butyl methacrylate, methylacrylate, isopropyl acrylate, cyclohexyl methacrylate, 2-methylcyclo hexylmethacrylate, dicyclopentenylacrylate, dicyclopentanylacrylate, dicyclopentenylmethacrylate, dicyclopentanylmethacrylate, 1-adamantyl acrylate, 1-adamantyl methacrylate, dicyclopentanyloxyethylmethacrylate, isoboronylmethacrylate, cyclohexylacrylate, 2-methylcyclohexylacrylate, dicyclopentanyloxyethylacrylate, isoboronylacrylate, phenylmethacrylate, phenylacrylate, benzylacrylate, 2-hydroxyethylmethacrylate, styrene, σ-methyl styrene, m-methyl styrene, p-methyl styrene, vinyltoluene, p-methoxy styrene, 1,3-butadiene, isoprene, 2,3-dimethyl 1,3-butadiene, acrylic acid glycidyl, methacrylic acid glycidyl, α-ethylacrylic acid glycidyl, α-n-propylacrylic acid glycidyl, α-n-butylacrylic acid glycidyl, acrylic acid-β-methylglycidyl, methacrylic acid-β-methylglycidyl, acrylic acid-β-ethylglycidyl, methacrylic acid-β-ethylglycidyl, acrylic acid-3,4-epoxybutyl, methacrylic acid-3,4-epoxybutyl, acrylic acid-6,7-epoxyheptyl, methacrylic acid-6,7-epoxyheptyl, α-ethylacrylic acid-6,7-epoxyheptyl, o-vinylbenzylglycidylether, m-vinylbenzylglycidylether, p-vinylbenzylglycidylether, and methacrylic acid 3,4-epoxycyclohexyl.

8. The photosensitive resin composition of claim 1, wherein:
a polystyrene-converted weight average molecular weight of the acryl-based copolymer is about 3000 to about 30000. [units?]

9. The photosensitive resin composition of claim 1, wherein:
the multifunctional acrylate oligomer has 2 to 20 functional groups and includes at least one selected from the group including an aliphatic urethane acrylate oligomer, an aromatic urethane acrylate oligomer, an epoxy acrylate oligomer, an epoxy methacrylate oligomer, a polyester acrylate oligomer, a silicon acrylate oligomer, a melamine acrylate oligomer, and a dendritic acrylate oligomer.

10. The photosensitive resin composition of claim 1, wherein:
the multifunctional monomer having the ethylenically unsaturated bond includes at least one selected from the group including 1,4-butanediol diacrylate, 1,3-butyleneglycol diacrylate, ethyleneglycol diacrylate, trimethylolpropane diacrylate, trimethylolpropane triacrylate, pentaerythritol triacrylate, pentaerythritol tetraacrylate, triethyleneglycol diacrylate, polyethyleneglycol diacrylate, dipentaerythritol hexadiacrylate, dipentaerythritol tridiacrylate, dipentaerythritol diacrylate, sorbitol triacrylate, a bisphenol A diacrylate derivative, dipentaerythritol polyacrylate, and methacrylates thereof.

11. The photosensitive resin composition of claim 1, further comprising:
a solvent so that a solid content is about 10 parts by weight to about 50 parts by weight of the entire photosensitive resin composition.

12. A method of forming a pattern, comprising:
applying a photosensitive resin composition on a substrate, and
exposing and developing the photosensitive resin composition,
wherein the photosensitive resin composition includes
an acryl-based copolymer formed by copolymerizing i) at least one of an unsaturated carboxylic acid, an unsaturated carboxylic acid anhydride, and a mixture thereof and at least one of an olefin-based unsaturated compound and a mixture of olefin-based unsaturated compounds,
a photoinitiator represented by the following Chemical Formula 1 or 2,
a multifunctional acrylate oligomer,
a multifunctional monomer having an ethylenically unsaturated bond, and
a melamine crosslinking agent: 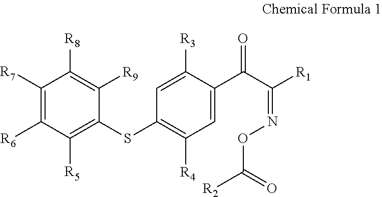
wherein, in Chemical Formula 1, R1 is an alkyl group having 1 to 8 carbon atoms, R2 is a phenyl group or an alkyl group having 1 to 8 carbon atoms, and R3 to R9 are each independently hydrogen, a halogen atom, or an alkyl group having 1 to 8 carbon atoms, and 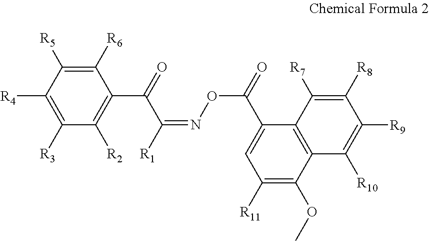
wherein in Chemical Formula 2, R1 is an alkyl group having 1 to 8 carbon atoms, and R2 to R11 are each independently hydrogen, a halogen atom, or an alkyl group having 1 to 8 carbon atoms.

13. The method of forming a pattern of claim 12, wherein:
the melamine crosslinking agent is represented by the following Chemical Formula 3: 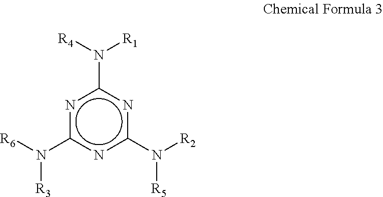
wherein in Chemical Formula 3, R1, R2, and R3 are each independently —CH₂O (CH₂)ₙCH³ (n is an integer of 0 to 3), and R4, R5, and R6 are each independently or simultaneously hydrogen, —(CH₂)OH, or —CH₂O (CH₂)ₙCH₃ (n is an integer of 0 to 3).

14. The method of forming a pattern of claim 13, wherein:
the photosensitive resin composition further includes a silane coupling agent.

15. The method of forming a pattern of claim 14, wherein:
a content of the acryl-based copolymer obtained after 5 parts by weight to 40 parts by weight of the acryl-base copolymer of the at least one of the unsaturated carboxylic acid, the unsaturated carboxylic acid anhydride, and the mixture thereof, and 60 parts by weight to 95 parts by weight of the acryl-base copolymer of the at least one of the olefin-based unsaturated compound or the mixture of olefin-based unsaturated compounds are copolymerized and an unreacted monomer is removed is about 100 parts by weight,
the content of the photoinitiator is about 0.1 parts by weight to about 30 parts by weight of the acryl-base copolymer,
the content of the multifunctional acrylate oligomer is about 1 part by weight to about 50 parts by weight of the acryl-base copolymer,
the content of the multifunctional monomer having the ethylenically unsaturated bond is about 1 part by weight to about 50 parts by weight of the acryl-base copolymer,
the content of the melamine crosslinking agent is about 0.1 parts by weight to about 30 parts by weight of the acryl-base copolymer, and
the content of the silane coupling agent is about 0.1 parts by weight to about 30 parts by weight of the acryl-base copolymer.

16. The method of forming a pattern of claim 15, wherein:
the photosensitive resin composition further includes a solvent so that a solid content is about 10 parts by weight to about 50 parts by weight of the entire photosensitive resin composition.
